(19) United States
(12) Patent Application Publication
(10) Pub. No.: US 2025/0308865 A1
(43) Pub. Date: Oct. 2, 2025

(54) SUBSTRATE PROCESSING APPARATUS AND ELECTROSTATIC CHUCK

(71) Applicant: Tokyo Electron Limited, Tokyo (JP)

(72) Inventor: Kohei OTSUKI, Miyagi (JP)

(73) Assignee: Tokyo Electron Limited, Tokyo (JP)

(21) Appl. No.: 19/237,332

(22) Filed: Jun. 13, 2025

Related U.S. Application Data
(63) Continuation of application No. PCT/JP2023/043800, filed on Dec. 7, 2023.
(60) Provisional application No. 63/476,487, filed on Dec. 21, 2022.

(51) Int. Cl. H01J 37/32

(52) U.S. Cl. CPC H01J 37/32724; H01J 37/32449; H01J 2237/2007

(57) ABSTRACT

An electrostatic chuck includes: an upper surface, and a chuck main body having at least one first gas supply path and at least one second gas supply path, protrusions, a first annular groove, a second annular groove surrounding the first annular groove, and an intermediate groove in an annular shape disposed between the first annular groove and the second annular groove and having a depth less than a depth of the first annular groove and a depth of the second annular groove are formed in the upper surface, the first annular groove communicates with the at least one first gas supply path via at least one first gas supply hole, and the second annular groove communicates with the at least one second gas supply path via at least one second gas supply hole.

### CROSS-REFERENCE TO RELATED APPLICATIONS

This application is a bypass continuation application of international application No. PCT/JP2023/043800 having an international filing date of Dec. 7, 2023 and designating the United States, the international application being based upon and claiming the benefit of priority from U.S. Ser. No. 63/476,487, filed on Dec. 21, 2022, the entire contents of each are incorporated herein by reference.

### TECHNICAL FIELD

The present disclosure relates to a substrate processing apparatus and an electrostatic chuck.

### BACKGROUND

PTL 1 discloses that an electrostatic chuck includes sealing bands located on a surface of the chuck. The sealing bands are in contact with a substrate to form a seal between adjacent cooling zones.

PTL 2 discloses that an outer peripheral ring that annularly surrounds an outermost periphery of a substrate holding surface of an electrostatic chuck is provided. The outer peripheral ring comes into contact with a substrate when the substrate is placed on the substrate holding surface.

### CITATION LIST

### Patent Documents

PTL 1: JP2020-512692A
PTL 2: JP2006-257495A

### SUMMARY

According to the technique of the present disclosure, a temperature of a substrate is appropriately controlled to improve the uniformity of plasma processing in a substrate surface.

A substrate processing apparatus according to one aspect of the present disclosure includes: a substrate processing chamber, a substrate support disposed in the substrate processing chamber and having at least one first gas supply path and at least one second gas supply path, the substrate support having a base and an electrostatic chuck disposed on the base and having an upper surface, protrusions, a first annular groove, a second annular groove that surrounds the first annular groove, and an intermediate groove in an annular shape disposed between the first annular groove and the second annular groove and having a depth less than a depth of the first annular groove and a depth of the second annular groove being formed in the upper surface, the first annular groove communicating with the at least one first gas supply path via at least one first gas supply hole, the second annular groove communicating with the at least one second gas supply path via at least one second gas supply hole, at least one first control valve configured to control a flow rate or a pressure of a gas supplied via the at least one first gas supply path, and at least one second control valve configured to control a flow rate or a pressure of a gas supplied via the at least one second gas supply path.

According to the present disclosure, the temperature of the substrate can be appropriately controlled to improve the uniformity of the plasma processing in the substrate surface.

### BRIEF DESCRIPTION OF DRAWINGS

FIG. 1 is a diagram schematically illustrating a configuration of a plasma processing system.

FIG. 2 is a vertical sectional view illustrating a schematic configuration of a plasma processing apparatus.

FIG. 3 is a plan view illustrating a schematic configuration of an electrostatic chuck according to a first embodiment.

FIG. 4 is a vertical sectional view illustrating the schematic configuration of the electrostatic chuck according to the first embodiment.

FIG. 5 is a sectional perspective view illustrating the schematic configuration of the electrostatic chuck according to the first embodiment and is a view illustrating a pressure distribution in a heat transfer space.

FIG. 6 is a plan view illustrating a schematic configuration of an electrostatic chuck according to a modification of the first embodiment.

FIG. 7 is a plan view illustrating a schematic configuration of an electrostatic chuck according to a second embodiment.

FIG. 8 is a plan view illustrating a schematic configuration of the electrostatic chuck according to the second embodiment.

FIG. 9 is a plan view illustrating a schematic configuration of an electrostatic chuck according to a comparative example.

FIGS. 10A and 10B are diagrams illustrating effects of the electrostatic chuck according to the second embodiment.

FIG. 11 is a plan view illustrating a schematic configuration of an electrostatic chuck according to a third embodiment.

FIG. 12 is a sectional perspective view illustrating the schematic configuration of the electrostatic chuck according to the third embodiment.

FIG. 13 is a diagram illustrating examples of physical property values of a porous member according to the third embodiment.

### DETAILED DESCRIPTION

In a production step of a semiconductor device, for example, a semiconductor substrate (hereinafter referred to as a “substrate”) is subjected to plasma processing in a plasma processing apparatus. In the plasma processing apparatus, a processing gas is excited in a chamber to generate a plasma, and the substrate supported by an electrostatic chuck is processed by the plasma.

In plasma processing, it is required to appropriately control the temperature of the substrate to be processed to improve in-plane uniformity of the plasma processing on the substrate. Therefore, for example, a heat transfer gas such as a helium gas is supplied to a space between a rear surface of the substrate and a surface of the electrostatic chuck, and the temperature of the substrate is controlled by controlling the pressure of the heat transfer gas.

In recent years, to meet the demands for even higher precision in controlling the temperature of the substrate, the space between the rear surface of the substrate and the surface of the electrostatic chuck is partitioned into regions, and a pressure difference in the heat transfer gas is provided between the regions, thereby controlling the temperature of the substrate for each region. In the related art, to control the pressure of the heat transfer gas for each region, for example, a partition referred to as a so-called seal band, which is in direct contact with the rear surface of the substrate, is provided on the surface of the electrostatic chuck. For example, PTL 1 discloses a configuration in which sealing bands are provided as the seal bands on the surface of the electrostatic chuck. PTL 2 described above discloses that an inner peripheral ring may be provided inside the outermost peripheral ring on the surface of the electrostatic chuck.

However, since the seal band is in direct contact with the rear surface of the substrate, the contact portion becomes a local temperature singularity. Specifically, the heat is transferred to the substrate in the contact portion, and the temperature of the substrate in the contact portion is reduced. The temperature singularity of the substrate affects the rate of the plasma processing, and as a result, the plasma processing may not be performed uniformly across the substrate surface. Therefore, the plasma processing in the related art has room for improvement.

The technique according to the present disclosure has been made in consideration of the circumstances described above, and controls the temperature of the substrate appropriately to improve the uniformity of the plasma processing in the substrate surface.

Hereinafter, the plasma processing apparatus and the electrostatic chuck according to the present embodiment will be described with reference to the drawings. The same reference numerals will be given to elements having substantially the same functional configurations throughout the specification and the drawings, and redundant description thereof will be omitted.

### <Plasma Processing System>

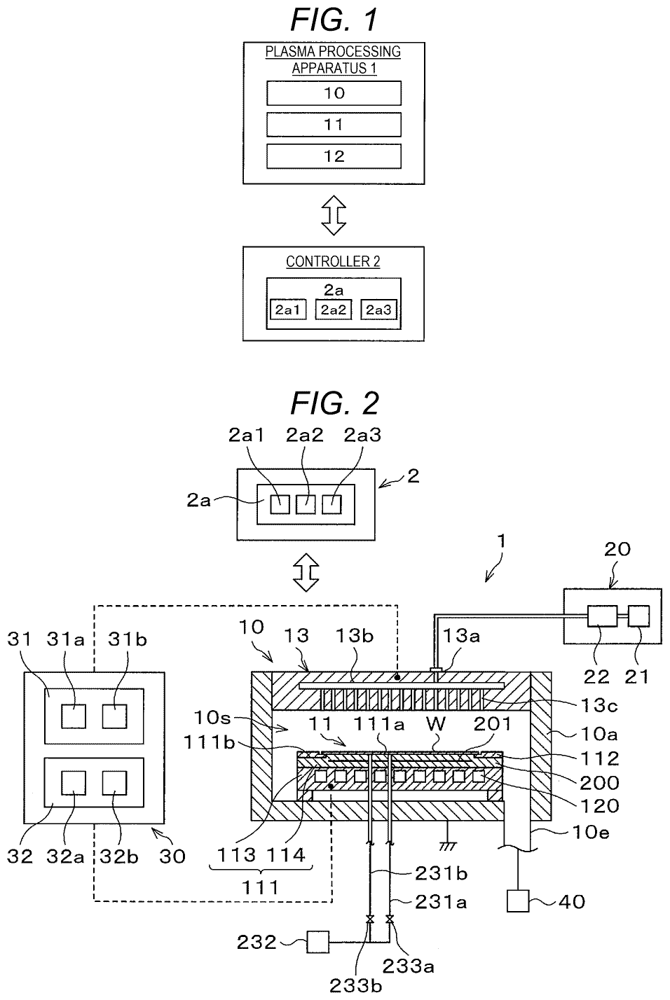

First, a plasma processing system according to an embodiment will be described. FIG. 1 is a diagram illustrating an example of a configuration of a plasma processing system.

In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10 as a substrate processing chamber, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be Capacitively Coupled Plasma (CCP), Inductively Coupled Plasma (ICP), Electron-Cyclotron-Resonance Plasma (ECR plasma), Helicon Wave Plasma (HWP), Surface Wave Plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include a processor 2a1, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### <Plasma Processing Apparatus>

Hereinafter, a configuration example of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, a power source 30, and the exhaust system 40. The plasma processing apparatus 1 further includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a support main body 111 and a ring assembly 112. An upper surface of the support main body 111 has a substrate support surface 111a that is a central region for supporting a substrate W and a ring support surface 111b that is an annular region for supporting the ring assembly 112. A wafer is an example of the substrate W. The ring support surface 111b of the support main body 111 surrounds the substrate support surface 111a of the support main body 111 in a plan view. The substrate W is disposed on the substrate support surface 111a of the support main body 111, and the ring assembly 112 is disposed on the ring support surface 111b of the support main body 111 to surround the substrate W on the substrate support surface 111a of the support main body 111.

In one embodiment, the support main body 111 includes a base 113 and an electrostatic chuck 114. The base 113 includes a conductive member. The conductive member of the base 113 may function as a lower electrode. The electrostatic chuck 114 is disposed on the base 113. The electrostatic chuck 114 includes a chuck main body 200 and an electrostatic electrode 201 disposed in the chuck main body 200. The chuck main body 200 has the substrate support surface 111a. In one embodiment, the chuck main body 200 also has the ring support surface 111b. Other members that surround the electrostatic chuck 114, such as an annular electrostatic chuck or an annular insulating member, may have the ring support surface 111b. In this case, the ring assembly 112 may be disposed on the annular electrostatic chuck or the annular insulating member, or may be disposed on both the electrostatic chuck 114 and the annular insulating member. At least one RF/DC electrode coupled to an RF power source 31 and/or a DC power source 32, which will be described later, may be disposed in the chuck main body 200. In this case, at least one RF/DC electrode functions as the lower electrode. When a bias RF signal and/or DC signal, which will be described later, is supplied to at least one RF/DC electrode, the RF/DC electrode is also referred to as a bias electrode. The conductive member of the base 113 and at least one RF/DC electrode may function as lower electrodes. The electrostatic electrode 201 may function as the lower electrode. The substrate support 11 therefore includes at least one lower electrode.

The ring assembly 112 includes one or more annular members. In one embodiment, the one or more annular members include one or more edge rings and at least one cover ring. The edge ring is made of an electrically conductive material or an insulating material, and the cover ring is made of an insulating material.

The substrate support 11 may include a temperature control module configured to adjust the temperature of at least one of the electrostatic chuck 114, the ring assembly 112, and the substrate W to a target temperature. The temperature control module may include a heater, a heat transfer medium, a flow path 120, or a combination thereof. A heat transfer fluid, such as brine or gas, flows through the flow path 120. In one embodiment, the flow path 120 is formed in the base 113, and one or more heaters are disposed in the chuck main body 200 of the electrostatic chuck 114. The substrate support 11 may include a heat transfer gas supply configured to supply the heat transfer gas to a gap between the rear surface of the substrate W and the substrate support surface 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thus generated from the at least one processing gas supplied into the plasma processing space 10s. Accordingly, the RF power source 31 may function as at least a part of the plasma generator 12. Supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate a bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. In one embodiment, the first DC generator 32a is connected to at least one lower electrode to generate a first DC signal. The generated first DC signal is applied to at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected, for example, to a gas discharge port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

### <Plasma Processing Method>

Next, plasma processing performed using the plasma processing system configured as described above will be described. As the plasma processing, for example, etching processing or film formation processing is performed.

First, the substrate W is loaded into the plasma processing chamber 10, and the substrate W is placed on the electrostatic chuck 114. Thereafter, by applying a DC voltage to the electrostatic electrode 201 of the electrostatic chuck 114, the substrate W is electrostatically attracted and held on the electrostatic chuck 114 by a coulomb force. At this time, the substrate W is adjusted to a desired temperature. Further, after the substrate W is carried in, the pressure inside the plasma processing chamber 10 is reduced to a desired vacuum level by the exhaust system 40.

Next, a processing gas is supplied from the gas supply 20 to the plasma processing space 10s through the shower head 13. Further, the first RF generator 31a of the RF power source 31 supplies the source RF power for plasma generation to the conductive member of the substrate support 11 and/or the conductive member of the shower head 13. Then, the processing gas is excited to generate the plasma. At this time, the second RF generator 31b may supply a bias RF signal for attracting ions. Then, the generated plasma acts to subject the substrate W to the plasma processing.

### First Embodiment

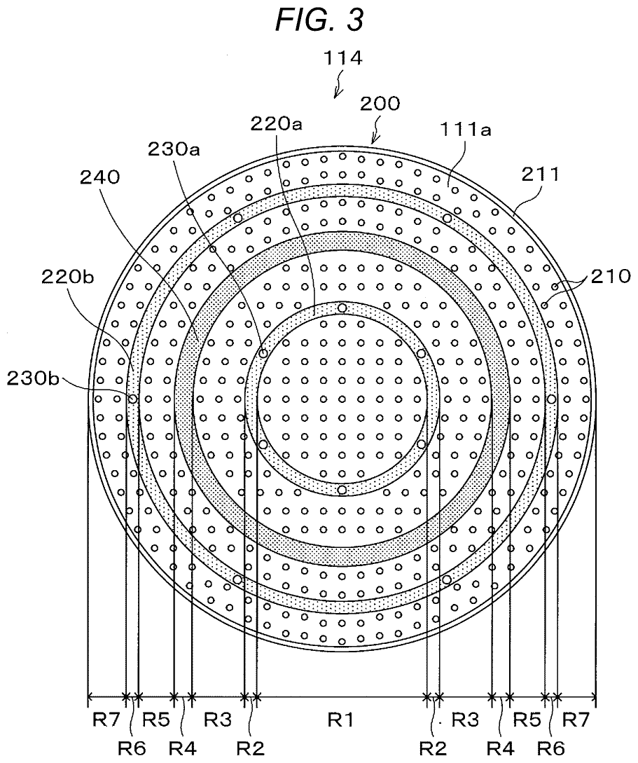

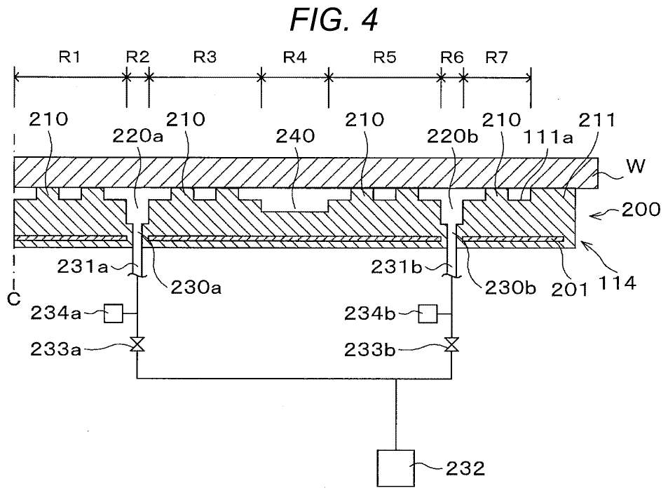

Next, the configuration of the electrostatic chuck 114 according to a first embodiment will be described. FIG. 3 is a plan view illustrating a schematic configuration of the electrostatic chuck 114. FIG. 4 is a vertical sectional view illustrating the schematic configuration of the electrostatic chuck 114. In FIG. 4, C indicates a center line of the electrostatic chuck 114.

As illustrated in FIGS. 3 and 4, the electrostatic chuck 114 includes the chuck main body 200. The chuck main body 200 is formed of a dielectric and is formed of, for example, ceramic such as alumina (Al₂O₃). The electrostatic chuck 114 has a substantially disc shape. For example, the electrostatic electrode 201 connected to the first DC generator 32a is provided in the chuck main body 200. By applying a direct-current voltage from the first DC generator 32a to the electrostatic electrode 201 to generate a coulomb force, the electrostatic chuck 114 can attract the substrate W. A heater (not illustrated) may be provided in the chuck main body 200.

An upper surface of the chuck main body 200 has the substrate support surface 111a for supporting the substrate W. The substrate support surface 111a is formed in, for example, a circle having a diameter less than that of the substrate W to be supported. Accordingly, when the substrate W is supported on the substrate support surface 111a, an outer peripheral portion of the substrate W protrudes outward from an end of the substrate support surface 111a.

The substrate support surface 111a of the chuck main body 200 includes substrate contact portions 210 serving as protrusions and an outer peripheral contact portion 211 serving as an outer peripheral protrusion. The substrate contact portion 210 is a dot having a columnar shape and is provided to protrude from the substrate support surface 111a. The substrate contact portions 210 are provided inside the outer peripheral contact portion 211. The outer peripheral contact portion 211 is provided in an annular shape protruding from the substrate support surface 111a at an outermost peripheral portion of the substrate support surface 111a. That is, the outer peripheral contact portion 211 is disposed to surround a first annular groove 220a, a second annular groove 220b, and an intermediate groove 240, which will be described later. The substrate contact portions 210 and the outer peripheral contact portion 211 are formed to have flat upper surfaces at the same height, and come into contact with the substrate W when the substrate W is supported by the electrostatic chuck 114. Therefore, the substrate W is supported by the substrate contact portions 210 and the outer peripheral contact portion 211.

At least one annular groove 220, two annular grooves 220a and 220b in the present embodiment, are formed in the substrate support surface 111a of the chuck main body 200. The annular grooves 220a and 220b are each recessed from the substrate support surface 111a and formed in an annular shape, and in the present embodiment, in a circular shape. The annular grooves 220a and 220b are disposed side by side in this order from the inside to the outside in a radial direction, and the second annular groove 220b is disposed to surround the first annular groove 220a. Central positions of the annular grooves 220a and 220b in a plan view are the same as a central position of the substrate support surface 111a. That is, the annular grooves 220a and 220b are disposed concentrically.

The annular grooves 220a and 220b each have a rectangular shape in a cross-sectional view. The annular grooves 220a and 220b have the same cross-sectional shape. In the following description, the annular grooves 220a and 220b may be collectively referred to as annular grooves 220.

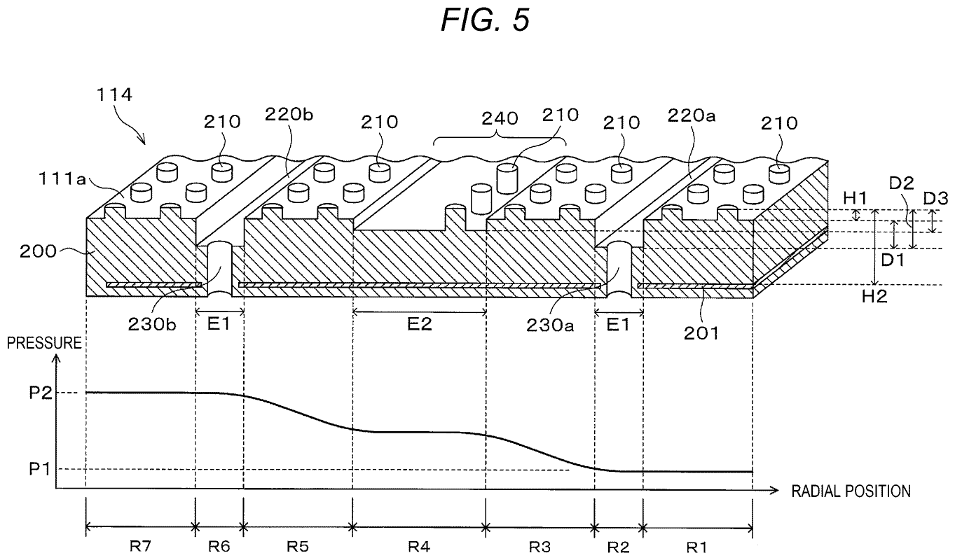

As illustrated in FIG. 5, a depth D1 (a depth from the substrate support surface 111a to a bottom of the annular groove 220) of the annular groove 220 is equal to or larger than a height H1 (a height from the substrate support surface 111a to an upper surface of the substrate contact portion 210) of the substrate contact portion 210. A depth D2 (a depth from the upper surface of the substrate contact portion 210 to the bottom of the annular groove 220) of the annular groove 220 is twice or more the height H1 of the substrate contact portion 210. For example, the height H1 of the substrate contact portion 210 is 5 μm to 20 μm, and the depth D2 of the annular groove 220 is 10 μm to 40 μm.

Upper limit values of the depths D1 and D2 of the annular groove 220 are not particularly limited. For example, the annular groove 220 may extend vertically downward until the bottom thereof is located slightly above the upper surface of the electrostatic electrode 201 without reaching the electrostatic electrode 201. For example, the depth D1 of the annular groove 220 may be half or less of a distance H2 from the upper surface of the substrate contact portion 210 to the upper surface of the electrostatic electrode 201.

A width E1 of the annular groove 220 is, for example, 0.3 mm to 10 mm. The width E1 of the annular groove 220 is also not particularly limited.

As illustrated in FIGS. 3 and 4, first heat transfer gas supply holes 230a serving as at least one first gas supply hole are formed in the first annular groove 220a. The first heat transfer gas supply hole 230a is formed penetrating the chuck main body 200 from a bottom of the first annular groove 220a. A first heat transfer gas supply path 231a serving as at least one first gas supply path is connected to the first heat transfer gas supply hole 230a, and the first heat transfer gas supply path 231a communicates with a heat transfer gas source 232. The first heat transfer gas supply path 231a is provided with at least one first control valve 233a and a first pressure gauge 234a from a side of the heat transfer gas source 232. An opening degree of the first control valve 233a is controlled such that the pressure detected by the first pressure gauge 234a becomes a desired pressure. Accordingly, the first control valve 233a is configured to control a flow rate or pressure of the heat transfer gas supplied from the heat transfer gas source 232 via the first heat transfer gas supply path 231a. The first control valve 233a and the first pressure gauge 234a may be integrally provided. The heat transfer gas supplied from the heat transfer gas source 232 is supplied to the first annular groove 220a through the first heat transfer gas supply path 231a and the first heat transfer gas supply hole 230a, and diffuses in a circumferential direction along the first annular groove 220a. The heat transfer gas is also supplied to a space (hereinafter, referred to as a “heat transfer space”) between the rear surface of the substrate W and the substrate support surface 111a.

Second heat transfer gas supply holes 230b serving as at least one second gas supply hole are formed in the second annular groove 220b. The second heat transfer gas supply hole 230b is formed penetrating the chuck main body 200 from a bottom of the second annular groove 220b. A second heat transfer gas supply path 231b serving as at least one second gas supply path is connected to the second heat transfer gas supply hole 230b, and the second heat transfer gas supply path 231b communicates with the heat transfer gas source 232. The second heat transfer gas supply path 231b is provided with at least one second control valve 233b and a second pressure gauge 234b from the side of the heat transfer gas source 232. The second control valve 233b and the second pressure gauge 234b have the same configurations as the first control valve 233a and the first pressure gauge 234a, respectively, and the second control valve 233b is configured to control the flow rate or the pressure of the heat transfer gas. Similar to the first annular groove 220a, the heat transfer gas supplied from the heat transfer gas source 232 through the second heat transfer gas supply path 231b and the second heat transfer gas supply hole 230b diffuses in the circumferential direction along the second annular groove 220b and is also supplied to the heat transfer space.

In the present embodiment, the heat transfer gas supply paths 231a and 231b merge and communicate with the common heat transfer gas source 232, and may communicate with individual heat transfer gas sources, respectively. In the present embodiment, the flow rate or the pressures of the heat transfer gas supplied from the heat transfer gas supply holes 230a and 230b are controlled by using the control valves 233 a and 233b, and in addition thereto, the flow rate or the pressures of the heat transfer gas may be controlled by changing diameters of the heat transfer gas supply holes 230a and 230b. As the heat transfer gas (backside gas), for example, a helium gas is used. In the following description, the heat transfer gas supply holes 230a and 230b may be collectively referred to as a heat transfer gas supply hole 230, the heat transfer gas supply paths 231a and 231b may be collectively referred to as a heat transfer gas supply path 231, the control valves 233a and 233b may be collectively referred to as a control valve 233, and the pressure gauges 234a and 234b may be collectively referred to as a pressure gauge 234.

The intermediate groove 240 that functions as a pressure adjustment groove, which will be described later, is formed in the substrate support surface 111a of the chuck main body 200. The intermediate groove 240 is recessed from the substrate support surface 111a and formed in an annular shape, and in the present embodiment, in a circular shape. The intermediate groove 240 is disposed between the first annular groove 220a and the second annular groove 220b. A central position of the intermediate groove 240 in a plan view is the same as the central position of the substrate support surface 111a. That is, the annular grooves 220a and 220b and the intermediate groove 240 are disposed concentrically.

The intermediate groove 240 has a rectangular shape in a cross-sectional view. As illustrated in FIG. 5, a depth D3 (a depth from the upper surface of the substrate contact portion 210 to a bottom of the intermediate groove 240) of the intermediate groove 240 is less than the depth D2 (the depth from the upper surface of the substrate contact portion 210 to the bottom of the annular groove 220) of the annular groove 220. For example, the height H1 of the substrate contact portion 210 is 5 μm to 20 μm, and the depth D3 of the intermediate groove 240 is 10 μm to 30 μm.

A width E2 of the intermediate groove 240 is equal to or larger than the width E1 of the annular groove 220. For example, the width E2 of the intermediate groove 240 is 10 mm to 50 mm. The width E2 of the intermediate groove 240 is not particularly limited.

As illustrated in FIGS. 3 and 4, the substrate support surface 111a is partitioned into seven regions R1 to R7 by the annular grooves 220a and 220b and the intermediate groove 240. The first region R1 is a circular region inside the first annular groove 220a in the radial direction. The second region R2 is an annular region in which the first annular groove 220a is formed. The third region R3 is an annular region between the first annular groove 220a and the intermediate groove 240. The fourth region R4 is an annular region in which the intermediate groove 240 is formed. The fifth region R5 is an annular region between the intermediate groove 240 and the second annular groove 220b. The sixth region R6 is an annular region in which the second annular groove 220b is formed. The seventh region R7 is an annular region between the second annular groove 220b and the outer peripheral contact portion 211. The substrate contact portions 210 described above are disposed in each of the regions R1, R3, R5, and R7.

For example, when the pressures of the heat transfer gases supplied from the heat transfer gas supply holes 230a and 230b are different from each other, the pressure of the heat transfer space is controlled for each of the seven regions R1 to R7. FIG. 5 is a view illustrating the pressures of the heat transfer spaces in the regions R1 to R7 when a pressure P2 of the heat transfer gas from the second heat transfer gas supply hole 230b is larger than a pressure P1 from the first heat transfer gas supply hole 230a. In a graph of FIG. 5, a vertical axis indicates the pressure in the heat transfer space, and a horizontal axis indicates a radial position of the substrate W in a specific direction.

The heat transfer gas from the first heat transfer gas supply hole 230a diffuses into the heat transfer spaces inside the first annular groove 220a in the radial direction, that is, the heat transfer spaces in the first region R1 and the second region R2. The pressures in the heat transfer spaces in the first region R1 and the second region R2 are substantially the same as the pressure P1 of the heat transfer gas from the first heat transfer gas supply hole 230a.

The heat transfer gas from the second heat transfer gas supply hole 230b diffuses into the heat transfer spaces outside the second annular groove 220b in the radial direction, that is, the heat transfer spaces in the sixth region R6 and the seventh region R7. The pressures in the heat transfer spaces in the sixth region R6 and the seventh region R7 are substantially the same as the pressure P2 of the heat transfer gas from the second heat transfer gas supply hole 230b.

As described above, the heat transfer gas diffuses in the circumferential direction along the first annular groove 220a, and the heat transfer gas diffuses in the circumferential direction along the second annular groove 220b. Between the heat transfer spaces between the first annular groove 220a and the second annular groove 220b, that is, between the heat transfer spaces in the regions R3 to R5 and the heat transfer spaces in the regions R1 and R2 inside in the radial direction, gas conductance in the heat transfer space decreases, and a differential pressure is generated. Similarly, between the heat transfer spaces in the regions R3 to R5 and the heat transfer spaces in the regions R6 and R7 outside in the radial direction, the gas conductance in the heat transfer space decreases, and a differential pressure is generated. That is, the pressures in the heat transfer spaces in the regions R3 to R5 change from P2 to P1 from the outside toward the inside in the radial direction.

The intermediate groove 240 is formed in the fourth region R4, and a radial change (hereinafter referred to as a “pressure gradient”) in the pressure in the heat transfer space is small or substantially constant in the intermediate groove 240. That is, in the regions R3 to R5 from the outside toward the inside in the radial direction, the pressure gradient is large in the heat transfer space in the fifth region R5, the pressure gradient is small in the heat transfer space in the fourth region R4, and the pressure gradient is large in the heat transfer space in the third region R3.

As described above, according to the present embodiment, it is possible to generate a differential pressure between the heat transfer spaces in the regions R3 to R5 and the heat transfer spaces in the regions R1 and R2, and to generate a differential pressure between the heat transfer spaces in the regions R3 to R5 and the heat transfer spaces in the regions R6 and R7. As a result, the pressure in the heat transfer space of each of the regions R1 to R7 can be controlled, thereby controlling the temperature of the substrate W for each of the regions R1 to R7. At this time, since the differential pressure can be generated without the electrostatic chuck 114 coming into contact with the substrate W by forming the annular grooves 220a and 220b, a local temperature singularity that occurs when the seal band comes into contact with the substrate does not occur as in the related art. Therefore, according to the present embodiment, temperature controllability of the substrate W can be improved, and the uniformity of the plasma processing in the substrate surface can be improved.

As described above, according to the present embodiment, when the substrate support surface 111a is partitioned into the regions R1 to R7, since the electrostatic chuck 114 does not come into contact with the substrate W, the seal band is not worn out and changes in shape as in the seal band in the related art. Therefore, a temporal change is unlikely to occur, and the pressures in the heat transfer spaces in the regions R1 to R7 can be appropriately controlled.

Here, when the intermediate groove 240 is not formed in the regions R3 to R5, the pressures in the heat transfer spaces in the regions R3 to R5 have a constant pressure gradient from the outside toward the inside in the radial direction. In this respect, according to the present embodiment, since the intermediate groove 240 is formed in the fourth region R4 in the regions R3 to R5, a flow of the heat transfer gas can be changed in the intermediate groove 240, and the pressure gradient of the heat transfer space in the fourth region R4 can be reduced. Therefore, a pressure distribution in the radial direction in the heat transfer space can be controlled more precisely. As a result, the temperature controllability of the substrate W can be further improved, and the uniformity of the plasma processing in the substrate surface can be further improved.

In simulation, as a comparative example, when the intermediate groove 240 is not formed in the regions R3 to R5, the pressure gradients of the heat transfer spaces cannot be controlled in the regions R3 to R5. Meanwhile, as an example, when the position of the intermediate groove 240 is changed and provided in the regions R3 to R5, the pressure gradients of the heat transfer spaces can be controlled according to the position of the intermediate groove 240 even when pressure conditions of the heat transfer gases supplied from the heat transfer gas supply holes 230a and 230b are the same.

In the regions R3 to R5, since there is no need to form the annular groove 220 similar to the annular grooves 220a and 220b, a supply system such as the heat transfer gas supply path 231, the control valve 233, and the pressure gauge 234 for supplying the heat transfer gas to the annular groove 220 becomes unnecessary. Therefore, the temperature controllability of the substrate W can be improved with a simple structure in which the intermediate groove 240 is formed.

The pressure gradient of the heat transfer space in the fourth region R4 can be controlled by the depth D3 of the intermediate groove 240. For example, when the depth D3 of the intermediate groove 240 is large, the pressure gradient of the heat transfer space in the fourth region R4 is small. On the other hand, for example, when the depth D3 of the intermediate groove 240 is small, the pressure gradient of the heat transfer space in the fourth region R4 is large. The pressure gradient of the heat transfer space in the fourth region R4 is determined and the depth D3 of the intermediate groove 240 is determined according to specifications required for the substrate W.

It has been found that when the depth D3 of the intermediate groove 240 is about half the depth D2 of the annular groove 220 as in the present embodiment, the effect of the intermediate groove 240 described above, that is, the effect of being able to control the pressure gradient of the heat transfer space in the fourth region R4 to be sufficiently small can be exhibited.

In the present embodiment, the depth D3 of the intermediate groove 240 is less than the depth D2 of the annular groove 220. However, the depth D3 of the intermediate groove 240 and the depth D2 of the annular groove 220 may be the same. Even in this case, the effect described above, that is, the effect of being able to control the pressure gradient of the heat transfer space in the fourth region R4 can be exhibited. An upper limit value of the depth D3 of the intermediate groove 240 is not particularly limited, and is preferably set to an extent that abnormal discharge can be prevented because there is a concern that the abnormal discharge may occur when the depth D3 is excessively large.

The pressure gradient of the heat transfer space in the fourth region R4 is also affected by the width E2 of the intermediate groove 240. For example, when the width E2 of the intermediate groove 240 is small, the pressure gradient of the heat transfer space in the fourth region R4 is large. On the other hand, for example, when the width E2 of the intermediate groove 240 is large, the pressure gradient of the heat transfer space in the fourth region R4 is small.

Further, according to the present embodiment, since the heat transfer gas diffuses along the circumferential direction in the annular grooves 220a and 220b, it is also possible to improve the temperature uniformity of the substrate W in the circumferential direction.

According to the present embodiment, since the outer peripheral contact portion 211, which contacts the substrate W, is provided at the outermost peripheral portion of the substrate support surface 111a, it is possible to prevent the heat transfer gas from flowing out of the heat transfer space even when the heat transfer gas is supplied to the heat transfer space inside the outer peripheral contact portion 211 in the radial direction.

### Modification of First Embodiment

In the electrostatic chuck 114 according to the embodiment described above, the substrate contact portion 210 may be provided in the intermediate groove 240 as illustrated in FIG. 5. In this case, even when the width E2 of the intermediate groove 240 is large, for example, the substrate W can be appropriately supported by the substrate contact portion 210.

The intermediate groove 240 in a circular shape is formed between the first annular groove 220a and the second annular groove 220b in the substrate support surface 111a of the electrostatic chuck 114 in the embodiment described above. However, the number, disposition, and shape of the intermediate groove 240 are not limited thereto.

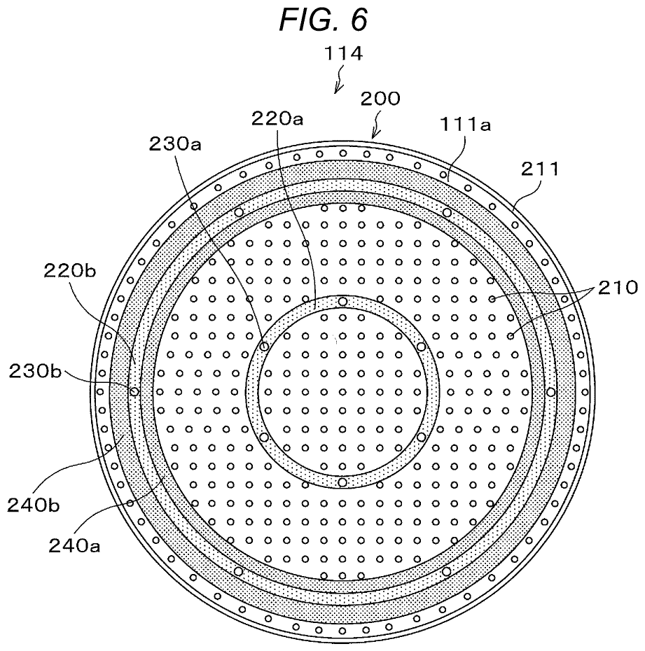

For example, as illustrated in FIG. 6, in the substrate support surface 111a, a first intermediate groove 240a may be formed between the first annular groove 220a and the second annular groove 220b, and a second intermediate groove 240b may be formed outward the second annular groove 220b in the radial direction. In the substrate support surface 111a, the intermediate groove 240 may not be formed between the first annular groove 220a and the second annular groove 220b, and the intermediate groove 240 in a circular shape may be formed only outside the second annular groove 220b in the radial direction. In other words, the intermediate groove 240 may be formed on an inner peripheral side or an outer peripheral side of the annular groove 220.

In the substrate support surface 111a, a plurality of the intermediate grooves 240 may be formed between the first annular groove 220a and the second annular groove 220b. Similarly, in the substrate support surface 111a, the intermediate grooves 240 may be formed outside the second annular groove 220b in the radial direction. As described above, regardless of the number and disposition of the intermediate grooves 240, the same effects as those of the embodiment described above can be obtained, that is, the pressure gradient of the heat transfer space in the region where the intermediate groove 240 is formed can be controlled.

In the embodiment described above, the intermediate groove 240 has a rectangular shape in a cross-sectional view. However, a cross-sectional shape of the intermediate groove 240 is not limited thereto. For example, the intermediate groove 240 may have a pentagonal shape in a cross-sectional view, and a bottom of the intermediate groove 240 may protrude in a vertical direction. A bottom surface of the intermediate groove 240 may protrude in the vertical direction and be curved. In either case, the effects of the intermediate groove 240 described above can be obtained.

In the embodiment described above, the intermediate groove 240 is formed in a circular shape. However, a planar shape of the intermediate groove 240 is not limited thereto, and may be in an annular shape. The intermediate groove 240 may have a polygonal shape or may have a central asymmetric shape different from the central position of the substrate support surface 111a. In either case, the effects of the intermediate groove 240 described above can be obtained.

In the embodiment described above, the intermediate groove 240 has a continuous annular shape. However, a part of the intermediate groove 240 may be discontinuous. At this time, the intermediate groove 240 may be discontinuous at one location, or may be discontinuous at a plurality of locations. In this way, the intermediate groove 240 may be formed by segments divided in the circumferential direction, and when the intermediate groove 240 is formed in an annular shape as a whole, the effects of the intermediate groove 240 described above can be obtained.

The first annular groove 220a and the second annular groove 220b are formed in the substrate support surface 111a according to the embodiment described above. However, the number, disposition, and shape of the annular groove 220 are not limited thereto.

### Second Embodiment

Next, a configuration of the electrostatic chuck 114 according to a second embodiment will be described. In the second embodiment, a disposition of the heat transfer gas supply holes 230 in the annular grooves 220 is optimized.

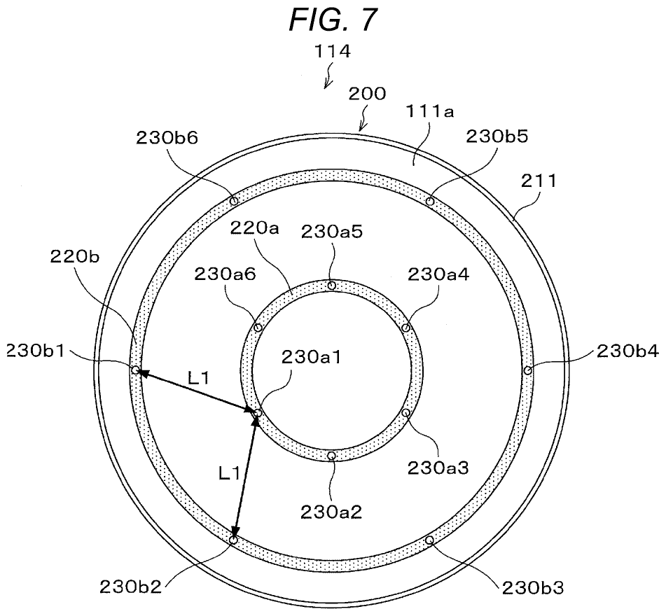

FIG. 7 illustrates an example in which two annular grooves including the first annular groove 220a and the second annular groove 220b are formed in the substrate support surface 111a. In FIG. 7, the substrate contact portion 210 is omitted for ease of illustration. The first annular groove 220a and the second annular groove 220b are disposed side by side in this order from the inside to the outside in the radial direction, and are disposed concentrically. A plurality of, for example, six first heat transfer gas supply holes 230al to 230a6 are formed in the first annular groove 220a at equal intervals in the circumferential direction. A plurality of heat transfer gas supply holes, for example, six second heat transfer gas supply holes 230b1 to 230b6 are formed in the second annular groove 220b at equal intervals in the circumferential direction.

The first heat transfer gas supply hole 230a is disposed at a position at which distances from two second heat transfer gas supply holes 230b disposed adjacent to each other in the circumferential direction are the same. That is, each first heat transfer gas 230a supply hole can be equidistant to two adjacent second heat transfer gas supply holes 230b. For example, the first heat transfer gas supply hole 230al is disposed at a position at which distances L1 from the second heat transfer gas supply hole 230b1 and the second heat transfer gas supply hole 230b2 disposed adjacent to each other in the circumferential direction are the same. Similarly, the second heat transfer gas supply hole 230b is disposed at a position at which distances from the two first heat transfer gas supply holes 230a disposed adjacent to each other in the circumferential direction are the same. That is, each second heat transfer gas 230b supply hole can be equidistant to two adjacent first heat transfer gas supply holes 230a. In the following description, such dispositions of the heat transfer gas supply holes 230a and 230b may be referred to as equidistant dispositions. In this case, the six first heat transfer gas supply holes 230al to 230a6 and the six second heat transfer gas supply holes 230b1 to 230b6 are disposed in a so-called staggered shape.

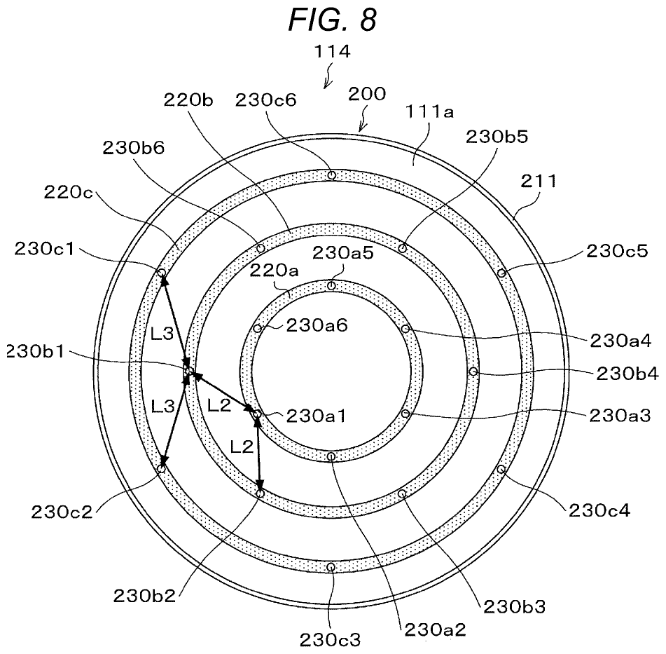

FIG. 8 illustrates an example in which three annular grooves including the first annular groove 220a, the second annular groove 220b, and a third annular groove 220c are formed in the substrate support surface 111a. In FIG. 8, the substrate contact portion 210 is also omitted for ease of illustration. The first annular groove 220a, the second annular groove 220b, and the third annular groove 220c are disposed side by side in this order from the inside to the outside in the radial direction, and are disposed concentrically. A plurality of, for example, six first heat transfer gas supply holes 230al to 230a6 are formed in the first annular groove 220a at equal intervals in the circumferential direction. A plurality of, for example, six second heat transfer gas supply holes 230b1 to 230b6 are formed in the second annular groove 220b at equal intervals in the circumferential direction. A plurality of, for example, six third heat transfer gas supply holes 230cl to 230c6 are formed in the third annular groove 220c at equal intervals in the circumferential direction.

The first heat transfer gas supply hole 230a is disposed at a position at which distances from two second heat transfer gas supply holes 230b disposed adjacent to each other in the circumferential direction are the same. For example, the first heat transfer gas supply hole 230al is disposed at a position at which distances L2 from the second heat transfer gas supply hole 230b1 and the second heat transfer gas supply hole 230b2 disposed adjacent to each other in the circumferential direction are the same. Similarly, the second heat transfer gas supply hole 230b is disposed at a position at which distances from the two first heat transfer gas supply holes 230a disposed adjacent to each other in the circumferential direction are the same.

The second heat transfer gas supply hole 230b is disposed at a position at which distances from two third heat transfer gas supply holes 230c disposed adjacent to each other in the circumferential direction are the same. For example, the second heat transfer gas supply hole 230b1 is disposed at a position at which distances L3 from the third heat transfer gas supply hole 230cl and the third heat transfer gas supply hole 230c2 disposed adjacent to each other in the circumferential direction are the same. Similarly, the third heat transfer gas supply hole 230c is disposed at a position at which distances from two second heat transfer gas supply holes 230b disposed adjacent to each other in the circumferential direction are the same.

As described above, dispositions of the heat transfer gas supply holes 230a, 230b, and 230c are equidistant dispositions. In this case, the six first heat transfer gas supply holes 230al to 230a6, the six second heat transfer gas supply holes 230b1 to 230b6, and the six third heat transfer gas supply holes 230cl to 230c6 are disposed in a so-called staggered shape.

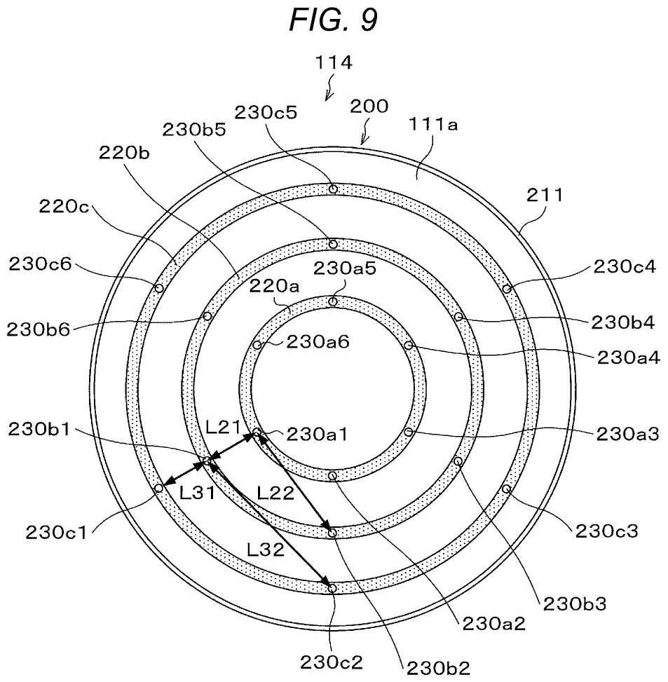

Effects of the present embodiment will be described with reference to a comparative example illustrated in FIG. 9. In FIG. 9, the substrate contact portion 210 is also omitted for ease of illustration. In the example illustrated in FIG. 9, three annular grooves including the first annular groove 220a, the second annular groove 220b, and the third annular groove 220c are formed in the substrate support surface 111a as in FIG. 8. However, dispositions of the heat transfer gas supply holes 230a, 230b, and 230c are not equidistant dispositions. For example, a distance L21 between the first heat transfer gas supply hole 230al and the second heat transfer gas supply hole 230b1 is different from a distance L22 between the first heat transfer gas supply hole 230al and the second heat transfer gas supply hole 230b2, and the distance L21 is less than the distance L22. For example, a distance L31 between the second heat transfer gas supply hole 230bl and the third heat transfer gas supply hole 230cl is different from a distance L32 between the second heat transfer gas supply hole 230bl and the third heat transfer gas supply hole 230c2, and the distance L31 is less than the distance

L32. Such dispositions of the heat transfer gas supply holes 230a, 230b, and 230c may be referred to as unequal distance dispositions.

In the example illustrated in FIG. 9, since the distance L21 between the first heat transfer gas supply hole 230al and the second heat transfer gas supply hole 230bl is small, the heat transfer gas flows more easily between the first heat transfer gas supply hole 230al and the second heat transfer gas supply hole 230b1 than between the first heat transfer gas supply hole 230al and the second heat transfer gas supply hole 230b2. Therefore, a differential pressure is less likely to be generated between a heat transfer space in the region inside the annular groove 220a in the radial direction and the heat transfer space in the region between the annular grooves 220a and 220b. Similarly, since the distance L31 between the second heat transfer gas supply hole 230b1 and the third heat transfer gas supply hole 230cl is small, the heat transfer gas flows easier between the second heat transfer gas supply hole 230b 1 and the third heat transfer gas supply hole 230cl than between the second heat transfer gas supply hole 230b1 and the third heat transfer gas supply hole 230c2. Therefore, a differential pressure is less likely to be generated between the heat transfer space in the region between the annular grooves 220a and 220b and the heat transfer space in the region between the annular grooves 220b and 220c. Therefore, the pressure in the heat transfer space of the substrate support surface 111a may not be appropriately controlled.

In this respect, when the dispositions of the heat transfer gas supply holes 230a and 230b are equidistant dispositions as illustrated in FIG. 8 of the present embodiment, the distance L2 between the heat transfer gas supply holes 230a and 230b can be increased. Therefore, a differential pressure can be increased between the heat transfer space in the region inside the annular groove 220a in the radial direction and the heat transfer space in the region between the annular grooves 220a and 220b. Similarly, when the disposition of the heat transfer gas supply holes 230b and 230c are equidistant dispositions, the distance L3 between the heat transfer gas supply holes 230b and 230c can be increased. Therefore, a differential pressure can be increased between the heat transfer space in the region between the annular grooves 220a and 220b and the heat transfer space in the region between the annular grooves 220b and 220c. Therefore, the pressure in the heat transfer space of the substrate support surface 111a can be appropriately controlled.

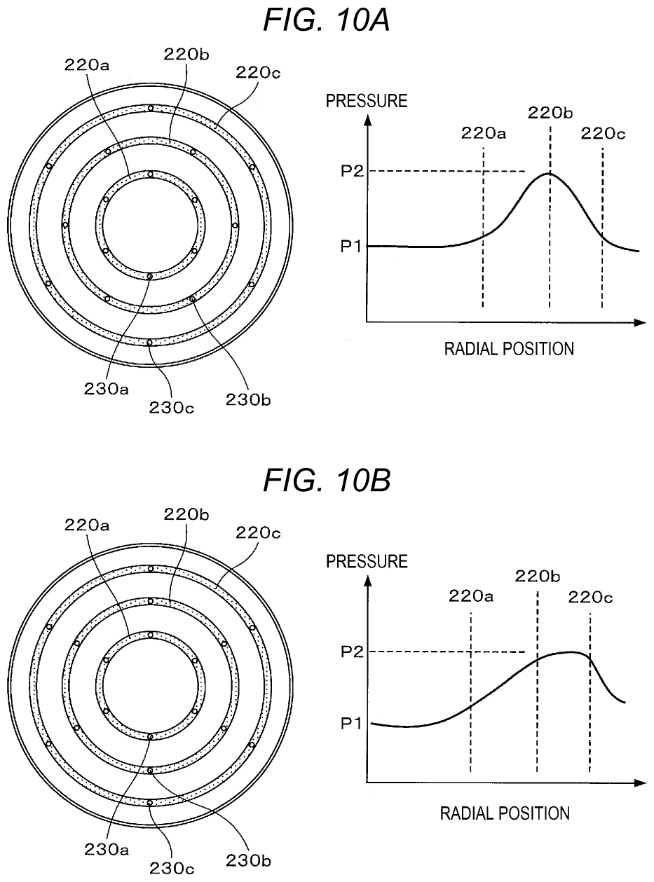

Next, results of testing the effects of the present embodiment will be described. The example illustrated in FIG. 10A is a case in which the dispositions of the heat transfer gas supply holes 230a, 230b, and 230c illustrated in FIG. 8 are equidistant dispositions, and the comparative example illustrated in FIG. 10B is a case in which dispositions of the heat transfer gas supply holes 230a, 230b, and 230c illustrated in FIG. 9 are unequal distance dispositions. Then, in the example and the comparative example, the pressure P2 of the heat transfer gas supplied from the second heat transfer gas supply hole 230b is larger than the pressure P1 of the heat transfer gas supplied from each of the first heat transfer gas supply hole 230a and the third heat transfer gas supply hole 230c. In each of graphs of FIGS. 10A and 10B, a vertical axis indicates the pressure in the heat transfer space, and a horizontal axis indicates a radial position of the substrate W in a specific direction.

In this case, in the case of the unequal distance dispositions as illustrated in FIG. 10B, a peak of the pressure in the heat transfer space is located at a position deviated from the second annular groove 220b toward the third annular groove 220c. The pressure distribution in the heat transfer space is different from the pressures of the heat transfer gases supplied from the heat transfer gas supply holes 230a, 230b, and 230c. Therefore, in the case of the unequal distance dispositions, the pressure in the heat transfer space cannot be appropriately controlled.

In this respect, in the case of the equidistant dispositions as illustrated in FIG. 10A, a peak of the pressure in the heat transfer space is a position of the second annular groove 220b. The pressure distribution in the heat transfer space is the same as the pressures of the heat transfer gases supplied from the heat transfer gas supply holes 230a, 230b, and 230c. Therefore, in the case of the equidistant dispositions, the pressure in the heat transfer space can be appropriately controlled. As a result, the temperature of the substrate W can be appropriately controlled.

In the examples illustrated in FIGS. 7 and 8, the dispositions of the heat transfer gas supply holes 230 are the equidistant dispositions. However, the dispositions of the heat transfer gas supply holes 230 are not limited thereto. For example, the effects of the present embodiment described above can be enjoyed and the pressure in the heat transfer space can be appropriately controlled as long as a minimum distance between the heat transfer gas supply holes 230 of the annular grooves 220 adjacent to each other in the radial direction is equal to or larger than a predetermined threshold value. The threshold value is determined according to the specifications required for the substrate W, and it is sufficient that the differential pressure between the regions is large enough to appropriately control the temperature of the substrate W.

In the examples illustrated in FIGS. 7 and 8, the dispositions of the heat transfer gas supply holes 230 are in a staggered shape. However, the dispositions of the heat transfer gas supply holes 230 are not limited thereto. For example, when the number of first heat transfer gas supply holes 230a formed in the first annular groove 220a and the number of second heat transfer gas supply holes 230b formed in the second annular groove 220b are different from each other, the dispositions of the heat transfer gas supply holes 230a and 230b may not be staggered dispositions. As described above, it is sufficient that the heat transfer gas supply holes 230a and 230b are in equidistant dispositions or the minimum distance between the heat transfer gas supply holes 230a and 230b is equal to or larger than a predetermined threshold value.

Two and three annular grooves 220 are formed in the substrate support surface 111a, respectively, in the examples illustrated in FIGS. 7 and 8. However, the number of the annular grooves 220 is not limited thereto. For example, four or more annular grooves 220 may be provided in the substrate support surface 111a.

In the examples illustrated in FIGS. 7 and 8, the intermediate groove 240 is not formed between the annular grooves 220. However, the intermediate groove 240 may be formed as illustrated in the first embodiment. In this case, the pressure in the heat transfer space can be more appropriately controlled.

### Third Embodiment

Next, a configuration of the electrostatic chuck 114 according to a third embodiment will be described. In the third embodiment, a porous member is provided in the annular groove 220.

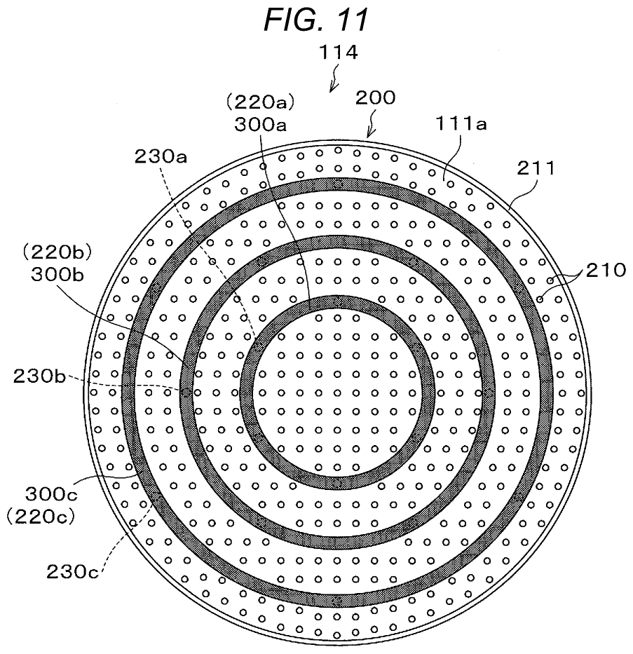

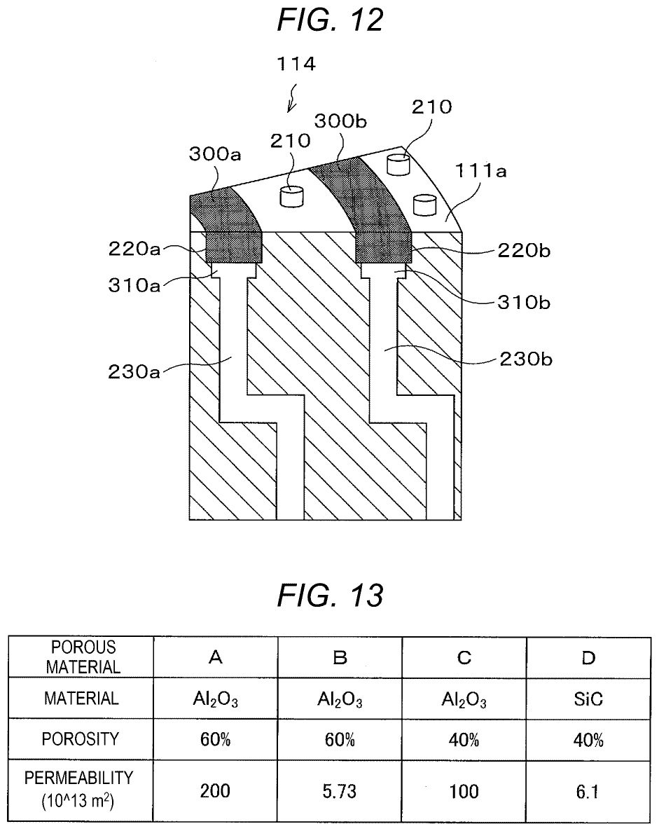

As illustrated in FIGS. 11 and 12, a first porous member 300a, a second porous member 300b, and a third porous member 300c are provided in the three annular grooves including the first annular groove 220a, the second annular groove 220b, and the third annular groove 220c provided in the substrate support surface 111a, respectively. The porous members 300a, 300b, and 300c each extend in the circumferential direction and are provided in a circular shape. The annular grooves 220a, 220b, and 220c are similar to the annular grooves 220a, 220b, and 220c illustrated in FIG. 8, respectively. In the following description, the porous members 300a, 300b, and 300c may be collectively referred to as a porous member 300.

Upper surfaces of the porous members 300a, 300b, and 300c are lower than the upper surface of the substrate contact portion 210. That is, when the substrate W is supported by the electrostatic chuck 114, the porous members 300a, 300b, and 300c do not come in contact with the substrate W.

As illustrated in FIG. 12, a first annular lower groove 310a and a second annular lower groove 310b are formed below the first porous member 300a and the second porous member 300b, respectively. Although not illustrated, a third annular lower groove 310c is also formed below the third porous member 300c. The annular lower grooves 310a, 310b, and 310c have the same shape as the annular grooves 220a, 220b, and 220c, respectively, and are formed in a circular shape. The heat transfer gas supply holes 230a, 230b, and 230c illustrated in FIG. 8 are formed in the annular lower grooves 310a, 310b, and 310c, respectively.

According to the present embodiment, since the first porous member 300a is provided to extend in the circumferential direction, the pressure of the heat transfer gas flowing through the first annular lower groove 310a below the first porous member 300a is uniform in the circumferential direction. Similarly, the pressures of the heat transfer gases flowing through the annular lower grooves 310b and 310c below the porous members 300b and 300c are also uniform in the circumferential direction.

In this case, for example, as illustrated in FIG. 12, between a heat transfer space between the porous members 300a and 300b and a heat transfer space inside the porous member 300a in the radial direction, gas conductance in the heat transfer space decreases, and a differential pressure is generated. In this way, when the pressure P2 of the heat transfer gas from the second heat transfer gas supply hole 230b is larger than the pressure P1 from the first heat transfer gas supply hole 230a, the pressure in the heat transfer space between the porous members 300a and 300b changes from P2 to P1 from the outside toward the inside in the radial direction. Therefore, according to the present embodiment, by providing the porous members 300a, 300b, and 300c, it is possible to obtain a pressure distribution similar to the pressure distribution in the heat transfer space obtained by the annular grooves 220a, 220b, and 220c even when the annular grooves 220a, 220b, and 220c are not provided.

By providing the porous members 300a, 300b, and 300c in the annular grooves 220a, 220b, and 220c, respectively, the side effect that the abnormal discharge can be prevented can also be obtained.

Here, it has been found that when a porosity of the porous member 300 is 45% to 75%, the effect described above, that is, the effect that the pressure of the heat transfer gas is uniform in the circumferential direction, can be obtained. For example, in a state in which the substrate W is not supported by the electrostatic chuck 114, the electrostatic chuck 114 may be dry cleaned by a plasma. In this case, since the porous member 300 is exposed to the plasma, it is preferable to use a material having plasma resistance for the porous member 300. Therefore, in view of the above, for example, porous materials A to D illustrated in FIG. 13 are used for the porous member 300. The porous materials A to D illustrated in FIG. 13 are examples, and for example, a porous body of a resin, such as polytetrafluoroethylene (PTFE), may be used.

In the present embodiment, the porosity of the porous material used for the porous members 300a, 300b, and 300c may be changed (i.e., may vary). For example, a porosity of the second porous member 300b may be less than a porosity of the first porous member 300a. The second porous member 300b has a larger circumferential length than a circumferential length of the first porous member 300a. Therefore, by reducing the porosity of the second porous member 300b, an amount of the heat transfer gas escaping from the second porous member 300b can be reduced, and the pressure in the second annular lower groove 310b can be easily made uniform in the circumferential direction. Similarly, for example, a porosity of the third porous member 300c may be less than the porosity of the second porous member 300b.

In the example illustrated in FIG. 11, the porous members 300a, 300b, and 300c are provided in all the three annular grooves 220a, 220b, and 220c. However, the porous member 300 may be provided in at least one of the annular grooves 220. When at least one porous member 300 is provided, the effects described above can be obtained.

Three annular grooves 220 are formed in the substrate support surface 111a in the example illustrated in FIG. 11. However, the number of the annular grooves 220 is not limited thereto. For example, two or four or more annular grooves 220 may be formed in the substrate support surface 111a.

In the example illustrated in FIG. 11, the intermediate groove 240 is not formed between the annular grooves 220. However, the intermediate groove 240 may be formed as illustrated in the first embodiment. In this case, the pressure in the heat transfer space can be more appropriately controlled.

In the example illustrated in FIG. 11, the dispositions of the heat transfer gas supply holes 230a, 230b, and 230c are equidistant dispositions (staggered dispositions) as in the second embodiment. However, the dispositions of the heat transfer gas supply holes 230a, 230b, and 230c are not limited thereto. Since the pressure of the heat transfer gas is made uniform in the circumferential direction by the porous members 300a, 300b, and 300c, it is sufficient that at least one of the heat transfer gas supply holes 230a, 230b, and 230c is formed.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

The following configuration examples also fall within the technical scope of the present disclosure.
(1)

A substrate processing apparatus including:
a substrate processing chamber,
a substrate support disposed in the substrate processing chamber and having at least one first gas supply path and at least one second gas supply path,
   the substrate support including a base and an electrostatic chuck that is disposed on the base and has an upper surface,
   protrusions, a first annular groove, a second annular groove surrounding the first annular groove, and an intermediate groove in an annular shape disposed between the first annular groove and the second annular groove and having a depth less than a depth of the first annular groove and a depth of the second annular groove being formed in the upper surface,
   the first annular groove communicating with the at least one first gas supply path via at least one first gas supply hole,
   the second annular groove communicating with the at least one second gas supply path via at least one second gas supply hole,
at least one first control valve configured to control a flow rate or a pressure of a gas supplied via the at least one first gas supply path, and
at least one second control valve configured to control a flow rate or a pressure of a gas supplied via the at least one second gas supply path.
(2)

The substrate processing apparatus according to (1), in which
a plurality of the first gas supply holes are formed in the first annular groove,
a plurality of the second gas supply holes are formed in the second annular groove, and
the first gas supply hole is formed at a position at which distances from two of the second gas supply holes disposed adjacent to each other in a circumferential direction are same.
(3)

The substrate processing apparatus according to (1) or (2), in which
a width of the intermediate groove is equal to or larger than a width of the first annular groove and a width of the second annular groove.
(4)

The substrate processing apparatus according to any one of (1) to (3), in which
the protrusions are provided in the intermediate groove.
(5)

The substrate processing apparatus according to any one of (1) to (4), in which
the upper surface has an outer peripheral protrusion in an annular shape that surrounds the first annular groove and the second annular groove.
(6)

The substrate processing apparatus according to any one of (1) to (5), in which
a porous member is provided in at least one of the first annular groove and the second annular groove.
(7)

The substrate processing apparatus according to (6), in which
an annular lower groove is disposed below the porous member, and
at least one of the at least one first gas supply hole and the at least one second gas supply hole is formed in the annular lower groove.
(8)

The substrate processing apparatus according to (6) or (7), in which
the porous member is provided in both the first annular groove and the second annular groove, and
a porosity of the porous member provided in the second annular groove is less than a porosity of the porous member provided in the first annular groove.
(9)

A substrate processing apparatus comprising:
a substrate processing chamber,
a substrate support disposed in the substrate processing chamber and having at least one gas supply path, the substrate support having a base and an electrostatic chuck disposed on the base and having an upper surface,
   protrusions, an annular groove, and an intermediate groove in an annular shape disposed on at least one of a radial inside and a radial outside of the annular groove and having a depth less than a depth of the annular groove being formed in the upper surface,
   the annular groove communicating with the at least one gas supply path via at least one gas supply hole, and
at least one control valve configured to control a flow rate or a pressure of a gas supplied via the at least one gas supply path.
(10)

A substrate processing apparatus including:
a substrate processing chamber,
a substrate support disposed in the substrate processing chamber and having at least one first gas supply path and at least one second gas supply path,
   the substrate support including a base and an electrostatic chuck that is disposed on the base and has an upper surface,
   protrusions, a first annular groove, and a second annular groove that surrounds the first annular groove being formed in the upper surface,
   the first annular groove communicating with the at least one first gas supply path via first gas supply holes,
   the second annular groove communicating with the at least one second gas supply path via second gas supply holes,
at least one first control valve configured to control a flow rate or a pressure of a gas supplied via the at least one first gas supply path, and
at least one second control valve configured to control a flow rate or a pressure of a gas supplied via the at least one second gas supply path, in which
the first gas supply hole is provided at a position at which distances from two of the second gas supply holes disposed adjacent to each other in a circumferential direction are same.
(11)

A substrate processing apparatus including:
a substrate processing chamber,
a substrate support disposed in the substrate processing chamber and having at least one first gas supply path and at least one second gas supply path,
   the substrate support including a base and an electrostatic chuck that is disposed on the base and has an upper surface,
   protrusions, a first annular groove, and a second annular groove surrounding the first annular groove being formed in the upper surface,
   the first annular groove communicating with the at least one first gas supply path via first gas supply holes,
   the second annular groove communicating with the at least one second gas supply path via second gas supply holes,
at least one first control valve configured to control a flow rate or a pressure of a gas supplied via the at least one first gas supply path, and
at least one second control valve configured to control a flow rate or a pressure of a gas supplied via the at least one second gas supply path, in which
a minimum distance between the first gas supply hole and the second gas supply hole is equal to or larger than a predetermined threshold value.
(12)

A substrate processing apparatus including:
a substrate processing chamber,
a substrate support disposed in the substrate processing chamber and having at least one first gas supply path and at least one second gas supply path,
   the substrate support including a base and an electrostatic chuck that is disposed on the base and has an upper surface,
   the upper surface having protrusions, a first annular groove, a second annular groove surrounding the first annular groove, a first porous member provided in the first annular groove, and a second porous member provided in the second annular groove,
   the first annular groove communicating with the at least one first gas supply path via at least one first gas supply hole,
   the second annular groove communicating with the at least one second gas supply path via at least one second gas supply hole,
at least one first control valve configured to control a flow rate or a pressure of a gas supplied via the at least one first gas supply path, and
at least one second control valve configured to control a flow rate or a pressure of a gas supplied via the at least one second gas supply path.
(13)

An electrostatic chuck including:
an upper surface, and
a chuck main body having at least one first gas supply path and at least one second gas supply path, in which
protrusions, a first annular groove, a second annular groove surrounding the first annular groove, and an intermediate groove in an annular shape disposed between the first annular groove and the second annular groove and having a depth less than a depth of the first annular groove and a depth of the second annular groove are formed in the upper surface,
the first annular groove communicates with the at least one first gas supply path via at least one first gas supply hole, and
the second annular groove communicates with the at least one second gas supply path via at least one second gas supply hole.
(14)

The electrostatic chuck according to (13), in which
a plurality of the first gas supply holes are formed in the first annular groove,
a plurality of the second gas supply holes are formed in the second annular groove, and
the first gas supply hole is formed at a position at which distances from two of the second gas supply holes disposed adjacent to each other in a circumferential direction are same.
(15)

The electrostatic chuck according to (13) or (14), in which
a width of the intermediate groove is equal to or larger than a width of the first annular groove and a width of the second annular groove.
(16)

The electrostatic chuck according to any one of (13) to (15), in which
the protrusions are provided in the intermediate groove.
(17)

The electrostatic chuck according to any one of (13) to (16), in which
the upper surface has an outer peripheral protrusion in an annular shape that surrounds the first annular groove and the second annular groove.
(18)

The electrostatic chuck according to any one of (13) to (17), in which
a porous member is provided in at least one of the first annular groove and the second annular groove.
(19)

The electrostatic chuck according to (18), in which
an annular lower groove is disposed below the porous member, and
at least one of the at least one first gas supply hole and the at least one second gas supply hole is formed in the annular lower groove.
(20)

The electrostatic chuck according to (18) or (19), in which
the porous member is provided in both the first annular groove and the second annular groove, and
a porosity of the porous member provided in the second annular groove is less than a porosity of the porous member provided in the first annular groove.
(21)

An electrostatic chuck including:
an upper surface, and
a chuck main body having at least one gas supply path, in which
protrusions, an annular groove, and an intermediate groove in an annular shape disposed on at least one of a radial inside and a radial outside of the annular groove and having a depth less than a depth of the annular groove are formed in the upper surface, and
the annular groove communicates with the at least one gas supply path via at least one gas supply hole.
(22)

An electrostatic chuck including:
an upper surface, and
a chuck main body having at least one first gas supply path and at least one second gas supply path, in which
protrusions, a first annular groove, and a second annular groove that surrounds the first annular groove are formed in the upper surface,
the first annular groove communicates with the at least one first gas supply path via first gas supply holes,
the second annular groove communicates with the at least one second gas supply path via second gas supply holes, and
the first gas supply hole is provided at a position at which distances from two of the second gas supply holes disposed adjacent to each other in a circumferential direction are same.
(23)

An electrostatic chuck including:
an upper surface, and
a chuck main body having at least one first gas supply path and at least one second gas supply path,
the upper surface including protrusions, a first annular groove, and a second annular groove that surrounds the first annular groove,
the first annular groove communicates with the at least one first gas supply path via first gas supply holes,
the second annular groove communicates with the at least one second gas supply path via second gas supply holes, and
a minimum distance between the first gas supply hole and the second gas supply hole is equal to or larger than a predetermined threshold value.
(24)

An electrostatic chuck including:
an upper surface, and
a chuck main body having at least one first gas supply path and at least one second gas supply path, in which
the upper surface has protrusions, a first annular groove, a second annular groove surrounding the first annular groove, a first porous member provided in the first annular groove, and a second porous member provided in the second annular groove,
the first annular groove communicates with the at least one first gas supply path via at least one first gas supply hole, and
the second annular groove communicates with the at least one second gas supply path via at least one second gas supply hole.

1. A substrate processing apparatus comprising:
a substrate processing chamber;
a substrate support disposed in the substrate processing chamber and having at least one first gas supply path and at least one second gas supply path, the substrate support including a base and an electrostatic chuck that is disposed on the base and an upper surface;
at least one first control valve configured to control a flow rate or a pressure of a gas supplied via the at least one first gas supply path; and
at least one second control valve configured to control a flow rate or a pressure of a gas supplied via the at least one second gas supply path, wherein
the upper surface of the substrate support includes:
protrusions;
a first annular groove;
a second annular groove surrounding the first annular groove; and
an intermediate groove in an annular shape disposed between the first annular groove and the second annular groove,
the intermediate groove has a depth less than a depth of the first annular groove and has a depth less than a depth of the second annular groove,
the first annular groove communicates with the at least one first gas supply path via at least one first gas supply hole, and
the second annular groove communicates with the at least one second gas supply path via at least one second gas supply hole;

2. The substrate processing apparatus according to claim 1, wherein
the first annular groove includes a plurality of the first gas supply holes,
the second annular groove includes a plurality of the second gas supply holes, and
each first gas supply hole positioned equidistant from two of the second gas supply holes disposed adjacent to each other in a circumferential direction.

3. The substrate processing apparatus according to claim 1, wherein
a width of the intermediate groove is equal to or larger than a width of the first annular groove and a width of the second annular groove.

4. The substrate processing apparatus according to claim 1, wherein
the protrusions are provided in the intermediate groove.

5. The substrate processing apparatus according to claim 1, wherein
the upper surface has an outer peripheral protrusion in an annular shape that surrounds the first annular groove and the second annular groove.

6. The substrate processing apparatus according to claim 1, wherein
a porous member is provided in at least one of the first annular groove and the second annular groove.

7. The substrate processing apparatus according to claim 6, wherein
an annular lower groove is disposed below the porous member, and
at least one of the at least one first gas supply hole and the at least one second gas supply hole is formed in the annular lower groove.

8. The substrate processing apparatus according to claim 6, wherein
the porous member is provided in both the first annular groove and the second annular groove, and
a porosity of the porous member provided in the second annular groove is less than a porosity of the porous member provided in the first annular groove.

9. An electrostatic chuck comprising:
an upper surface, and
a chuck main body having at least one first gas supply path and at least one second gas supply path, wherein
the upper surface includes:
protrusions;
a first annular groove;
a second annular groove surrounding the first annular groove; and
an intermediate groove in an annular shape disposed between the first annular groove and the second annular groove,
the intermediate groove has a depth less than a depth of the first annular groove and has a depth of the second annular groove,
the first annular groove communicates with the at least one first gas supply path via at least one first gas supply hole, and
the second annular groove communicates with the at least one second gas supply path via at least one second gas supply hole.

10. The electrostatic chuck according to claim 9, wherein
the first annular groove includes a plurality of the first gas supply holes,
the second annular groove includes a plurality of the second gas supply holes, and
each first gas supply hole is positioned equidistant from two of the second gas supply holes disposed adjacent to each other in a circumferential direction.

11. The electrostatic chuck according to claim 9, wherein
a width of the intermediate groove is equal to or larger than a width of the first annular groove and a width of the second annular groove.

12. The electrostatic chuck according to claim 9, wherein
the protrusions are provided in the intermediate groove.

13. The electrostatic chuck according to claim 9, wherein
the upper surface has an outer peripheral protrusion in an annular shape that surrounds the first annular groove and the second annular groove.

14. The electrostatic chuck according to claim 9, wherein
a porous member is provided in at least one of the first annular groove and the second annular groove.

15. The electrostatic chuck according to claim 14, wherein
an annular lower groove is disposed below the porous member, and
at least one of the at least one first gas supply hole and the at least one second gas supply hole is formed in the annular lower groove.

16. The electrostatic chuck according to claim 14, wherein
the porous member is provided in both the first annular groove and the second annular groove, and
a porosity of the porous member provided in the second annular groove is less than a porosity of the porous member provided in the first annular groove.

17. An electrostatic chuck comprising:
an upper surface, and
a chuck main body including:
at least one first gas supply path;
at least one second gas supply path; and
a plurality of protrusions for contacting a substrate, wherein
the upper surface includes:
a first annular groove;
a second annular groove surrounding the first annular groove; and
an intermediate groove in an annular shape disposed between the first annular groove and the second annular groove,
the intermediate groove has a depth less than a depth of the first annular groove and has a depth of the second annular groove,
the intermediate groove includes protrusions among the plurality of protrusions,
the first annular groove communicates with the at least one first gas supply path via at least one first gas supply hole, and
the second annular groove communicates with the at least one second gas supply path via at least one second gas supply hole.

18. The electrostatic chuck according to claim 17, wherein
the first annular groove includes a plurality of the first gas supply holes, and
the second annular groove includes a plurality of the second gas supply holes.

19. The electrostatic chuck according to claim 17, wherein each first gas supply hole positioned equidistant from two of the second gas supply holes disposed adjacent to each other in a circumferential direction.

20. The electrostatic chuck according to claim 17, further comprising a porous member provided in at least one of the first annular groove and the second annular groove, wherein
an annular lower groove is disposed below the porous member, and
at least one of the at least one first gas supply hole and the at least one second gas supply hole is formed in the annular lower groove.
